(19) United States
(12) Patent Application Publication
(10) Pub. No.: US 2025/0392804 A1
(43) Pub. Date: Dec. 25, 2025

(54) ELECTRONIC DEVICE

(71) Applicant: Samsung Display Co., Ltd., Yongin-si (KR)

(72) Inventors: Jaebum Cho, Yongin-si (KR); Daewook Kim, Yongin-si (KR); Sungjae Park, Yongin-si (KR); Jewon Yoo, Yongin-si (KR); Hyunjoo Hwang, Yongin-si (KR)

(73) Assignee: Samsung Display Co., Ltd., Yongin-si (KR)

(21) Appl. No.: 19/245,627

(22) Filed: Jun. 23, 2025

(30) Foreign Application Priority Data
Jun. 21, 2024 (KR) 10-2024-0081368

(51) Int. Cl. H04N 23/55; H04N 23/57; H10H 29/80

(52) U.S. Cl. CPC H04N 23/55; H10H 29/842; H04N 23/57

(57) ABSTRACT

An electronic device includes a camera sensor unit including a short side and a long side, a camera lens unit disposed on the camera sensor unit, a display panel disposed on the camera lens unit, and a protective film disposed on the display panel and having birefringence, wherein the protective film has a refractive index n₁ in a first direction perpendicular to a thickness direction of the protective film, a refractive index n₂ in a second direction perpendicular to each of the thickness direction and the first direction, and a refractive index n₃ in the thickness direction, and the refractive index n₁ is greater than the refractive index n₂ and the refractive index n₃, and the first direction of the protective film and a direction the short side of the camera sensor unit extends are parallel to each other.

### CROSS-REFERENCE TO RELATED APPLICATION

This application claims priority to and benefits of Korean Patent Application No. 10-2024-0081368 under 35 USC § 119, filed on Jun. 21, 2024, in the Korean Intellectual Property Office (KIPO), the entire contents of which are incorporated herein by reference.

### BACKGROUND

### 1. Field

Embodiments relate to an electronic device.

### 2. Description of the Related Art

An electronic device including display device visually displays data. An electronic device including display device may provide images by using light-emitting diodes. The uses of electronic devices including display device are becoming more diverse, and various designs are being attempted to improve the quality of electronic devices including display device.

### SUMMARY

Embodiments provide an electronic device.

Additional aspects will be set forth in part in the description which follows and, in part, will be apparent from the description, or may be learned by practice of the embodiments of the disclosure.

According to an embodiment, an electronic device may include a camera sensor unit including a short side and a long side, a camera lens unit disposed on the camera sensor unit, a display panel disposed on the camera lens unit, and a protective film disposed on the display panel and having birefringence. The protective film may have a refractive index n₁ in a direction that provides the maximum refractive index and is perpendicular to a thickness direction of the protective film, a refractive index n₂ in a direction perpendicular to each of the direction of n₁ and the thickness direction, and a refractive index n₃ in the thickness direction, the refractive index n₁ may be greater than the refractive index n₂ and the refractive index n₃, and the first direction of the protective film and a direction the short side of the camera sensor unit extends may be parallel to each other.

An angle of view θ of the camera lens unit in the direction the short side of the camera sensor unit extends may be defined by Mathematical Formula 1.

$$θ = 2 atan \frac{L}{2 f} \qquad [ Mathematical Formula 1 ]$$

L may be a length of the short side of the camera sensor unit, and f may be a focal length of the camera lens unit.

The refractive index n₁, the refractive index n₂, and the refractive index n₃ may satisfy Mathematical Formula 2 2.

$${n}_{1} > {n}_{2} > {n}_{3} \qquad [ Mathematical Formula 2 ]$$

In case that linearly polarized light passes through the protective film and the camera lens unit, a light pattern may appear on the camera sensor unit.

An angle β between a center of the camera lens unit and a center of the light pattern from the camera lens unit may be defined by Mathematical Formula 3.

$$β = atan \{ \frac{{n}_{3}}{{n}_{1}} \sqrt{\frac{{( {n}_{2} )}^{2} - {( {n}_{1} )}^{2}}{{( {n}_{3} )}^{2} - {( {n}_{2} )}^{2}}} \} \qquad [ Mathematical Formula 3 ]$$

The angle of view e of the camera lens unit and the angle β between the center of the camera lens unit and the center of the light pattern may satisfy Mathematical Formula 4.

$$β \geq θ / 2 \qquad [ Mathematical Formula 4 ]$$

The angle of view θ of the camera lens unit and the angle β between the center of the camera lens unit and the center of the light pattern may satisfy Mathematical Formula 5.

$$θ / 2 - 5 ° \leq β \leq θ / 2 \qquad [ Mathetmatical Formula 5 ]$$

The refractive index n₁, the refractive index n₂, and the refractive index n₃ may satisfy Mathematical Formula 6.

$${n}_{1} > {n}_{3} > {n}_{2} \qquad [ Mathematical Formula 6 ]$$

In case that linearly polarized light passes through the protective film and the camera lens unit, the light pattern may appear on the camera sensor unit.

An angle β between the center of the camera lens unit and the center of the light pattern from the camera lens unit may be defined by Mathematical Formula 7.

$$β = atan \{ \frac{{n}_{2}}{{n}_{1}} \sqrt{\frac{{( {n}_{3} )}^{2} - {( {n}_{1} )}^{2}}{{( {n}_{2} )}^{2} - {( {n}_{3} )}^{2}}} \} \qquad [ Mathematical Formula 7 ]$$

The angle of view θ of the camera lens unit and the angle β between the center of the camera lens unit and the center of the light pattern may satisfy Mathematical Formula 4.

$$β \geq θ / 2 \qquad [ Mathematical Formula 4 ]$$

The angle of view e of the camera lens unit and the angle β between the center of the camera lens unit and the center of the light pattern may satisfy Mathematical Formula 5.

$$θ / 2 - 5 ° \leq β \leq θ / 2 \qquad [ Mathematical Formula 5 ]$$

The protective film may include polyethylene terephthalate (PET).

The display panel may include a first display area and a second display area surrounding at least a portion of the first display area.

The camera sensor unit and the camera lens unit may overlap at least a portion of the first display area of the display panel in a thickness direction of the display panel.

The first direction of the protective film may be a stretching direction of the protective film.

According to an embodiment, an electronic device may include a camera sensor unit including a short side and a long side, a camera lens unit disposed on the camera sensor unit, a display panel disposed on the camera lens unit, and a protective film disposed on the display panel and having birefringence. The protective film may have a refractive index n₁ in a direction that provides the maximum refractive index and is perpendicular to a thickness direction of the protective film, a refractive index n₂ in a direction perpendicular to each of the direction of n₁ and the thickness direction, and a refractive index n₃ in the thickness direction, which satisfy Mathematical Formula 2.

$${n}_{1} > {n}_{2} > {n}_{3} \qquad [ Mathematical Formula 2 ]$$

An angle of view θ of the camera lens unit in a direction the short side of the camera sensor unit extends may be defined by Mathematical Formula 1.

$$θ = 2 atan \frac{L}{2 f} \qquad [ Mathematical Formula 1 ]$$

L may be a length of the short side of the camera lens unit, f may be a focal length of the camera lens unit, in case that linearly polarized light passes through the protective film and the camera lens unit, an light pattern may appear on the camera sensor unit, an angle β between a center of the camera lens unit and a center of the light pattern from the camera lens unit may be defined by Mathematical Formula 3.

$$β = atan \{ \frac{{n}_{3}}{{n}_{1}} \sqrt{\frac{{( {n}_{2} )}^{2} - {( {n}_{1} )}^{2}}{{( {n}_{3} )}^{2} - {( {n}_{2} )}^{2}}} \} \qquad [ Mathematical Formula 3 ]$$

The angle of view θ of the camera lens unit and the angle β between the center of the camera lens unit and the center of the light pattern may satisfy Mathematical Formula 8.

$$θ / 2 - 5 ° \leq β \qquad [ Mathematical Formula 8 ]$$

The angle of view θ of the camera lens unit and the angle β between the center of the camera lens unit and the center of the light pattern may satisfy Mathematical Formula 4.

$$β \geq θ / 2 \qquad [ Mathematical Formula 4 ]$$

According to an embodiment, an electronic device may include a camera sensor unit including a short side and a long side, a camera lens unit disposed on the camera sensor unit, a display panel disposed on the camera lens unit, and a protective film disposed on the display panel and having birefringence. The protective film may have a refractive index n₁ in a direction that provides the maximum refractive index and is perpendicular to a thickness direction of the protective film, a refractive index n₂ in a direction perpendicular to each of the direction of n₁ and the thickness direction, and a refractive index n₃ in the thickness direction, which satisfy Mathematical Formula 6.

$${n}_{1} > {n}_{3} > {n}_{2} \qquad [ Mathematical Formula 6 ]$$

An angle of view θ of the camera lens unit in a direction the short side of the camera sensor unit extends may be defined by Mathematical Formula 1.

$$θ = 2 a tan \frac{L}{2 f} \qquad [ Mathematical Formula 1 ]$$

L may be a length of the short side of the camera lens unit, and f may be a focal length of the camera lens unit.

In case that linearly polarized light passes through the protective film and the camera lens unit, an light pattern may appear on the camera sensor unit, an angle β between a center of the camera lens unit and a center of the light pattern grom the camera lens may be defined by Mathematical Formula 7.

$$β = a tan \{ \frac{{n}_{2}}{{n}_{1}} \sqrt{\frac{{( {n}_{3} )}^{2} - {( {n}_{1} )}^{2}}{{( {n}_{2} )}^{2} - {( {n}_{3} )}^{2}}} \} \qquad [ Mathematical Formula 7 ]$$

The angle of view θ of the camera lens unit and the angle β between the center of the camera lens unit and the center of the light pattern may satisfy Mathematical Formula 8.

$$θ / 2 - 5 ° \leq β \qquad [ Mathematical Formula 8 ]$$

The angle of view θ of the camera lens unit and the angle β between the center of the camera lens unit and the center of the light pattern may satisfy Mathematical Formula 4.

$$β \geq θ / 2 \qquad [ Mathematical Formula 4 ]$$

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of an electronic device according to an embodiment;

FIGS. 2 and 3 are schematic perspective views of a foldable electronic device according to an embodiment;

FIG. 4 is a schematic plan view of an electronic device according to another embodiment;

FIG. 5A is a schematic cross-sectional view illustrating the electronic device taken along line A-A′ of FIG. 1 according to an embodiment;

FIG. 5B is a schematic cross-sectional view illustrating the electronic device taken along line B-B′ of FIG. 1 according to an embodiment;

FIGS. 6 and 7 are schematic diagrams of a portion of a display device according to an embodiment; and

FIG. 8 is a schematic diagram of a comparative example for explaining the effects of the disclosure.

### DETAILED DESCRIPTION OF THE EMBODIMENTS

As the disclosure allows for various changes and numerous embodiments, embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus repeated descriptions thereof are omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that when a layer, region, or component is referred to as being connected to another layer, region, or component, it can be directly or indirectly connected to the other layer, region, or component. For example, intervening layers, regions, or components may be present. For example, it will be understood that when a layer, region, or component is referred to as being electrically connected to another layer, region, or component, it can be directly or indirectly electrically connected to the other layer, region, or component. For example, intervening layers, regions, or components may be present.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

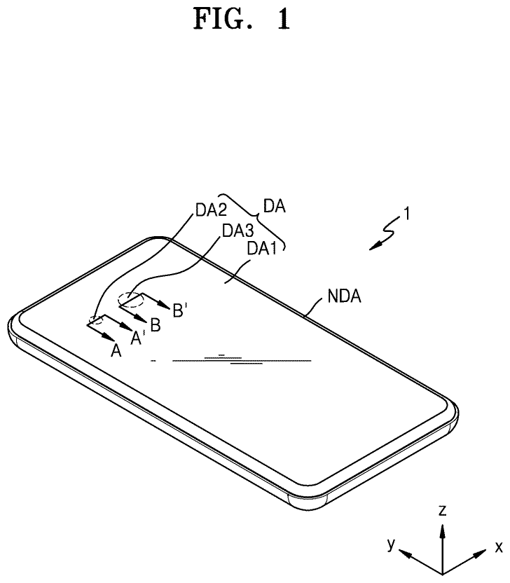

FIG. 1 is a perspective view of an electronic device 1 according to an embodiment.

The electronic device 1 according to an embodiment may be a device that displays video or still images, may be a portable electronic device such as a mobile phone, a smartphone, a tablet personal computer (PC), a mobile communication terminal, an electronic notebook, an electronic book, a portable multimedia player (PMP), a navigation device, or an ultra mobile PC (UMPC), and may also be used as a display screen in various products, such as televisions, laptop computers, monitors, advertisement boards, and Internet of things (IoT) devices. In another embodiment, the electronic device 1 may be applied to wearable devices such as smart watches, watch phones, glasses-type displays, and head mounted displays (HMDs). In an embodiment, the electronic device 1 may be used as a dashboard of a vehicle, a center fascia of a vehicle, a center information display (CID) arranged on a dashboard of a vehicle, a mirror display replacing a side mirror of a vehicle, or a display screen disposed on the back side of a front seat for entertainment for a passenger in a back seat of a vehicle. For convenience of explanation, FIG. 1 shows that the electronic device 1 is used as a smartphone.

Referring to FIG. 1, the electronic device 1 may include a display area DA and a non-display area NDA adjacent to the display area DA. The electronic device 1 may provide images through an array of multiple pixels, which are two-dimensionally arranged in the display area DA.

The non-display area NDA may be an area which does not provide images and may entirely surround the display area DA. A driver or the like for providing electrical signals or power to display elements arranged in the display area DA may be arranged in the non-display area NDA. A pad, which is an area to which an electronic device or a printed circuit board may be electrically connected, may be arranged in the non-display area NDA.

The display area DA may include a first display area DA1, a second display area DA2, and a third display area DA3. The second display area DA2 and the third display area DA3 may be areas in which components for adding various functions to the electronic device 1 are arranged, and the second display area DA2 may be a component area.

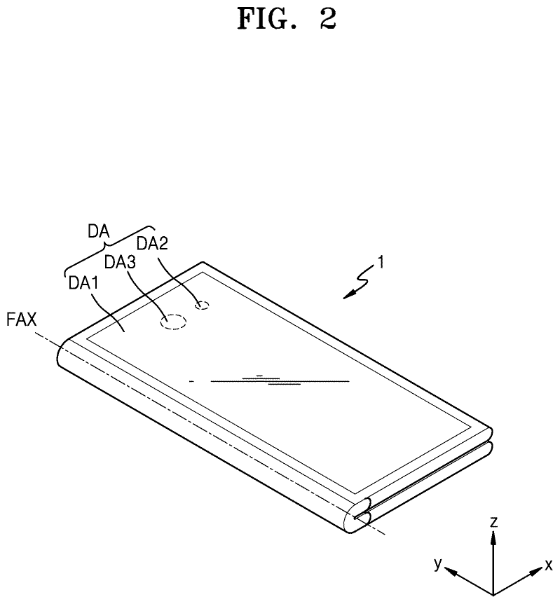

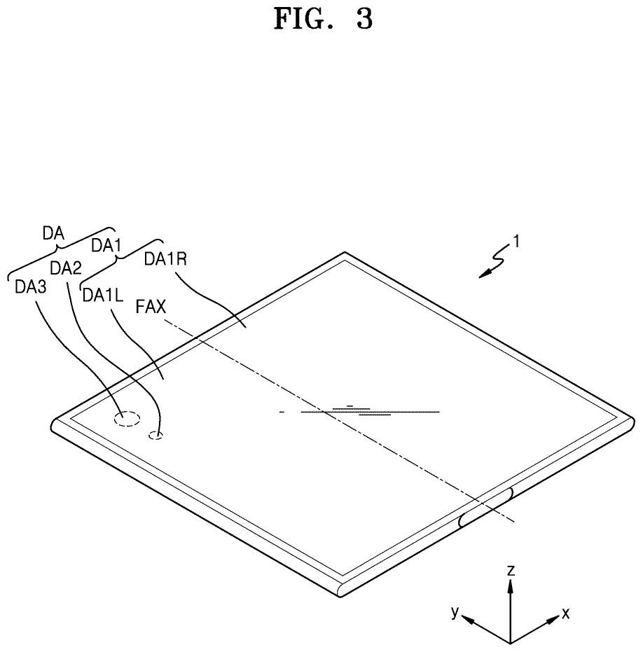

FIGS. 2 and 3 are schematic perspective views of a foldable electronic device according to an embodiment. FIG. 2 shows a folded state of the foldable electronic device, and FIG. 3 shows an unfolded state of the foldable electronic device.

The electronic device 1 according to an embodiment may be a foldable electronic apparatus. The electronic device 1 may be foldable around a folding axis FAX. The display area DA may be positioned on an outer side and/or an inner side of the electronic device 1. In an embodiment, as shown in FIGS. 2 and 3, the display area DA may be positioned on each of the outer side and the inner side of the electronic device 1.

Referring to FIG. 2, the display area DA may be arranged on the outer side of the electronic device 1. An outer side surface of the folded electronic device 1 may include the display area DA, and the display area DA may include the first display area DA1 occupying most of the display area DA, and the second display area DA2 and the third display area DA3, which have relatively small areas as compared to the first display area DA1.

Referring to FIG. 3, the display area DA may be arranged on the inner side of the electronic device 1. An inner side surface of the electronic device 1 that is unfolded may include the display area DA, and the display area DA may include the first display area DA1 occupying most of the display area DA, and the second display area DA2 and the third display area DA3, which have relatively small areas as compared to the first display area DA1.

FIG. 3 shows that the first display area DA1 includes a left display area DA1L and a right display area DA1R, which are positioned on sides of the folding axis FAX, respectively, and the second display area DA2 and the third display area DA3 are positioned inside the left display area DA1L, but the disclosure is not limited thereto. In another embodiment, the second display area DA2 and the third display area DA3 may be arranged in the right display area DA1R. In another embodiment, one of the second display area DA2 and the third display area DA3 may be arranged in the left display area DA1L, and another one of the second display area DA2 and the third display area DA3 may be arranged in the right display area DA1R.

As shown in FIGS. 1, 2, and 3, the area of each of the second display area DA2 and the third display area DA3 may be less than the area of the first display area DA1. The second display area DA2 and the third display area DA3 may have different sizes (areas), and in this regard, FIGS. 1 and 2 show that the size (area) of the second display area DA2 is less than the size (area) of the third display area DA3.

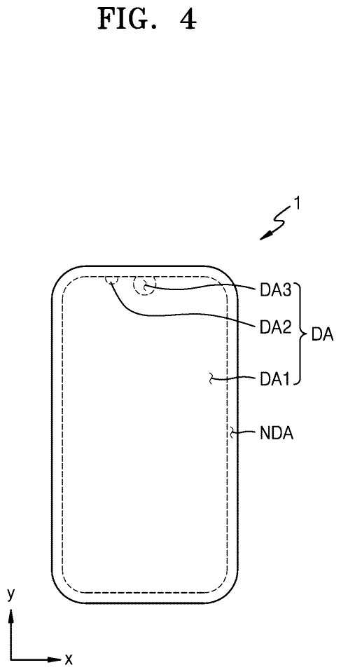

FIGS. 1, 2, and 3 show that each of the second display area DA2 and the third display area DA3 is entirely surrounded by the first display area DA1, but the disclosure is not limited thereto. FIG. 4 is a schematic plan view of an electronic device according to another embodiment. As shown in FIG. 4, each of the second display area DA2 and the third display area DA3 may be partially surrounded by the first display area DA1.

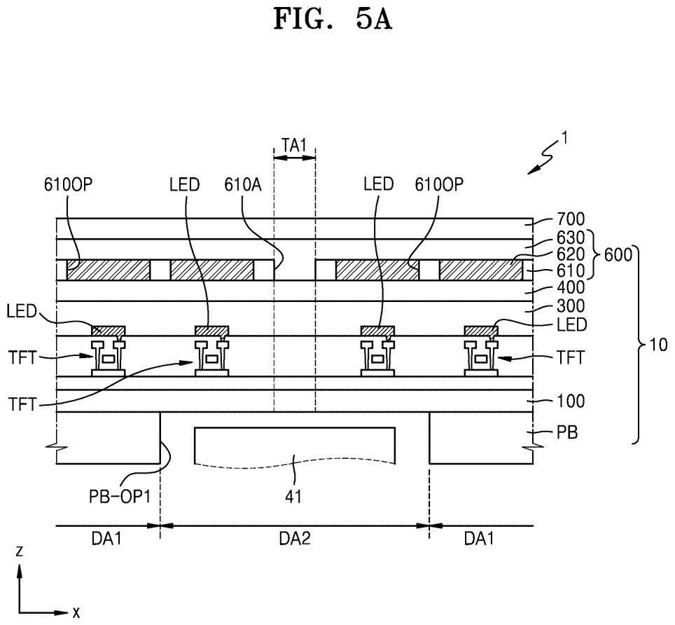

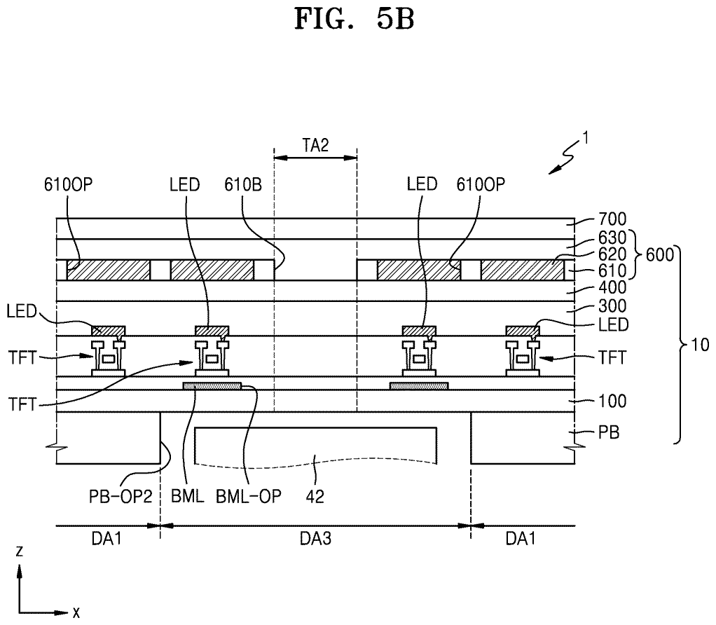

FIGS. 5A and 5B are schematic cross-sectional views each illustrating a portion of an electronic device according to an embodiment.

Referring to FIGS. 5A and 5B, the electronic device 1 may include a display panel 10 and a component disposed on a lower surface of the display panel 10 to overlap the display panel 10 in a thickness direction of the display panel 10. A first component 41 may be arranged in the second display area DA2, and a second component 42 may be arranged in the third display area DA3.

The display panel 10 may include a substrate 100, a thin-film transistor TFT disposed on the substrate 100, a display element (e.g., a light-emitting diode LED) electrically connected to the thin-film transistor TFT, an encapsulation layer 300 covering the display element, an input sensing layer 400, an anti-reflection layer 600, and a protective film 700.

The substrate 100 may include glass or a polymer resin. The substrate 100 including a polymer resin may be flexible, foldable, rollable, or bendable. The substrate 100 may have a multi-layered structure including a layer including the above-described polymer resin, and an inorganic layer (not shown).

A lower protective film PB may be disposed on the lower surface of the substrate 100. The lower protective film PB may be attached to the lower surface of the substrate 100. An adhesive layer may be disposed between the lower protective film PB and the substrate 100. In another embodiment, the lower protective film PB may be formed on (e.g., directly formed on) a rear surface of the substrate 100, and an adhesive layer may not be located between the lower protective film PB and the substrate 100.

The lower protective film PB may support and protect the substrate 100. The lower protective film PB may have openings PB-OP1 and PB-OP2 corresponding to the second display area DA2 and the third display area DA3, respectively. The lower protective film PB may include an organic insulating material such as polyethylene terephthalate (PET) or polyimide (PI).

The thin-film transistor TFT and the light-emitting diode LED, which is a display element electrically connected to the thin-film transistor TFT, may be disposed on the upper surface of the substrate 100. The light-emitting diode LED may be an organic light-emitting diode including an organic material. The organic light-emitting diode may emit red, green, or blue light.

In another embodiment, the light-emitting diode LED may be an inorganic light-emitting diode including an inorganic material. The inorganic light-emitting diode may include a PN junction diode including an inorganic semiconductor material. In case that a voltage is applied to the PN junction diode in a forward direction, holes and electrons may be injected, and energy generated by recombination of the holes and electrons may be converted into light energy to emit light of a color. The above-described inorganic light-emitting diode may have a width of several to several hundred micrometers, or several to several hundred nanometers. In some embodiments, the light-emitting diode LED may include a quantum dot light-emitting diode. An emission layer of the light-emitting diode LED may include an organic material, an inorganic material, quantum dots, an organic material and quantum dots, or an inorganic material and quantum dots.

The light-emitting diode LED may be electrically connected to the thin-film transistor TFT disposed below the light-emitting diode LED. The thin-film transistor TFT and the light-emitting diode LED may be arranged in each of the first display area DA1, the second display area DA2, and the third display area DA3.

A transmission area may be positioned in the second display area DA2 and the third display area DA3. As shown in FIG. 5A, a transmission area (for example, a first transmission area TA1) between neighboring light-emitting diodes LED may be arranged in the second display area DA2, and a transmission area (for example, a second transmission area TA2) between neighboring light-emitting diodes LED may be arranged in the third display area DA3.

The first transmission area TA1 and the second transmission area TA2 may be respectively areas through which light emitted from the first component 41 and the second component 42 and/or light directed toward the first component 41 and the second component 42 may pass. In the display panel 10, the transmittance of each of the first transmission area TA1 and the second transmission area TA2 may be greater than or equal to about 30%. For example, the transmittance of each of the first transmission area TA1 and the second transmission area TA2 may be about 40% or more, about 50% or more, about 60% or more, about 70% or more, about 75% or more, about 80% or more, about 85% or more, or about 90% or more.

The first component 41 and the second component 42 may each include a sensor such as a proximity sensor, an illuminance sensor, an iris sensor, and a facial recognition sensor, and a camera (or an image sensor). Each of the first component 41 and the second component 42 may use light. For example, the first component 41 and the second component 42 may emit and/or receive light of infrared, ultraviolet, and/or visible light bands. A proximity sensor using infrared light may detect an object arranged close to the upper surface of the electronic device 1, and an illuminance sensor may detect the brightness of light incident on the upper surface of the electronic device 1. An iris sensor may capture an image of an iris of a person arranged above the upper surface of the electronic device 1, and a camera may receive light relating to an object arranged above the upper surface of the electronic device 1.

The first component 41 and the second component 42 may be different from each other. In some embodiments, the first component 41 may include a sensor such as a proximity sensor, an illuminance sensor, an iris sensor, and a facial recognition sensor, and the second component 42 may include a camera (or an image sensor).

To prevent the functionality of the thin-film transistor TFT arranged in the second display area DA2 and/or the third display area DA3 from being reduced as a result of light passing through the first transmission area TA1 and/or the second transmission area TA2, a light-blocking metal layer BML may be arranged between the substrate 100 and the thin-film transistor TFT. In an embodiment, as shown in FIG. 5B, the light-blocking metal layer BML may be positioned in the third display area DA3. The light-blocking metal layer BML may include an opening BML-OP corresponding to (overlapping) the second transmission area TA2. The light-blocking metal layer BML may not be positioned in the first display area DA1 and the second display area DA2. In another embodiment, a light-blocking metal layer including an opening corresponding to the first transmission area TA1 may also be arranged in the second display area DA2.

The encapsulation layer 300 may cover the light-emitting diodes LED. The encapsulation layer 300 may include at least one inorganic encapsulation layer and at least one organic encapsulation layer.

The input sensing layer 400 may be formed on the encapsulation layer 300. The input sensing layer 400 may obtain coordinate information according to an external input, for example, a touch event of an object such as a finger or a stylus pen. The input sensing layer 400 may include a touch electrode and trace lines connected to the touch electrode. The input sensing layer 400 may sense an external input in a mutual-cap method or a self-cap method.

The anti-reflection layer 600 may reduce the reflectance of light (external light) incident from the outside toward the display panel 10. The anti-reflection layer 600 may include a light-blocking layer 610, color filters 620, and an overcoat layer 630. The light-blocking layer 610 may include openings 610OP overlapping the light-emitting diodes LED in the first display area DA1, the second display area DA2, and the third display area DA3 in the thickness direction, and the color filters 620 may be arranged in the openings 610OP described above, respectively.

The light-blocking layer 610 may include an opening portion (hereinafter referred to as a transmission opening portion) corresponding to a transmission area, for example, the first transmission area TA1 and the second transmission area TA2. The light-blocking layer 610 may include a first transmission opening portion 610A corresponding to the first transmission area TA1 provided in the second display area DA2 as shown in FIG. 5A and a second transmission opening portion 610B corresponding to the second transmission area TA2 provided in the third display area DA3 as shown in FIG. 5B.

The overcoat layer 630 may include a colorless transmissive material, and a portion of the overcoat layer 630 may at least partially fill the first transmission opening portion 610A and the second transmission opening portion 610B.

The protective film 700 may be disposed on the anti-reflection layer 600. The protective film 700 may include polyethylene terephthalate (PET). In the case of a foldable display device, the protective film 700 may be disposed on the anti-reflection layer 600 because glass is not used as the top protective layer.

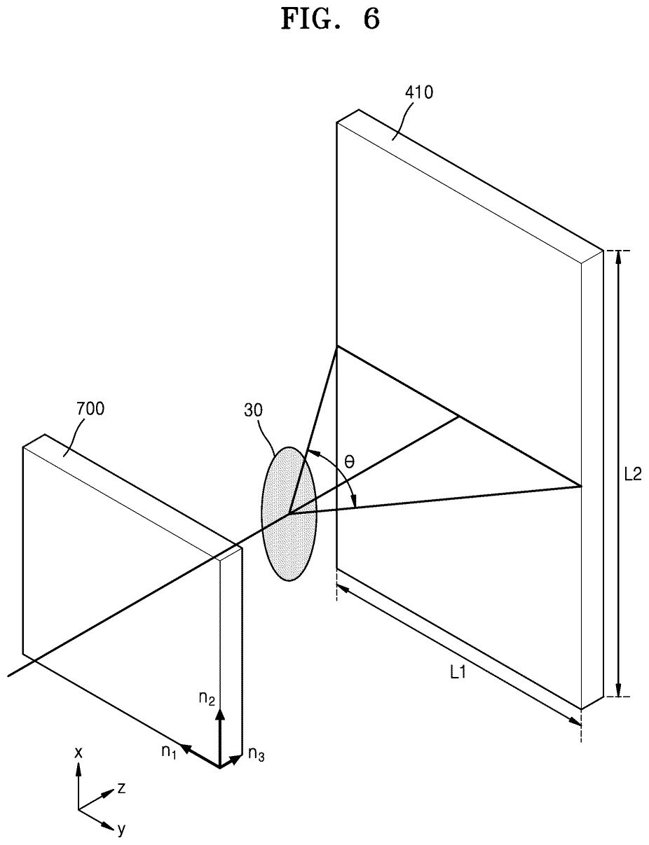

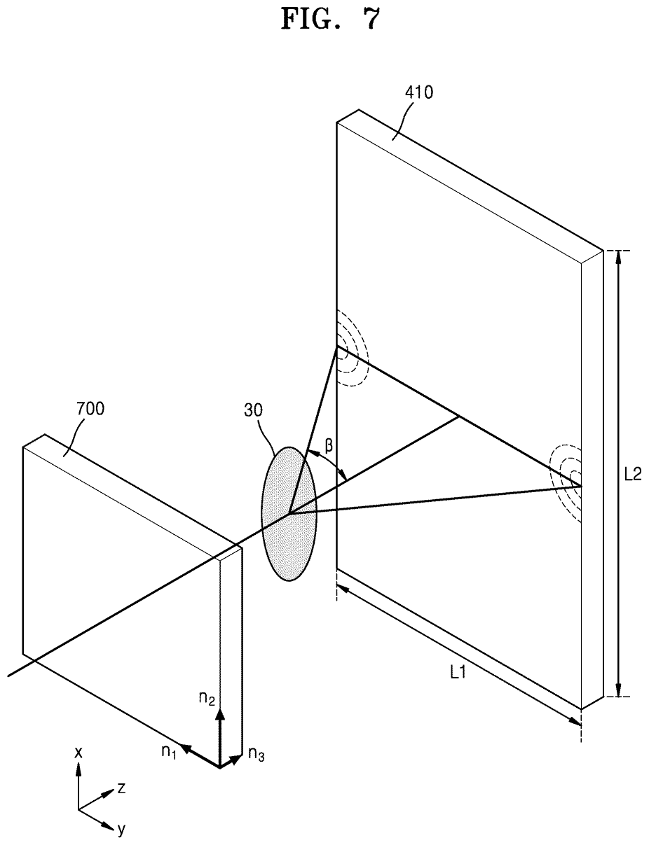

FIGS. 6 and 7 are schematic diagrams of a portion of a display device according to an embodiment. FIG. 6 illustrates an angle of view of a camera lens unit of a display device according to an embodiment, and FIG. 7 illustrates a light pattern appearing on a camera sensor unit of a display device according to an embodiment.

Referring to FIG. 6, the electronic device 1 may include a camera sensor unit 410 as the first component 41 (see FIG. 5A) and as the second component 42 (see FIG. 5B) according to an embodiment. The camera sensor unit 410 may include a long side L2 and a short side L1. A camera lens unit 30 may be disposed above the camera sensor unit 410. The protective film 700 may be disposed above the camera lens unit 30. Although not shown, the display panel 10 (see FIG. 5A) may be disposed between the protective film 700 and the camera lens unit 30.

The protective film 700 shown in FIG. 6 may be a portion of the protective film 700 disposed in the second display area DA2 (see FIG. 1) or the third display area DA3 (see FIG. 1) overlapping the components described in FIGS. 1 to 4.

The protective film 700 may have birefringence. The protective film 700 may have a refractive index n₁ in a first direction (e.g., y direction or −y direction) perpendicular to a thickness direction of the protective film 700 (e.g., z direction or −z direction). The first direction (e.g., y direction or −y direction) perpendicular to the thickness direction of the protective film 700 may be a stretching direction of the protective film 700. The protective film 700 may have a refractive index n₂ in a second direction (e.g., x direction or −x direction) perpendicular to each of the thickness direction (e.g., z direction or −z direction) of the protective film 700 and the first direction (e.g., y direction or −y direction). The protective film 700 may have a refractive index n₃in the thickness direction of the protective film 700 (e.g., z-direction or −z direction). The refractive index n₁ of the protective film 700 in the first direction (e.g., y direction or −y direction) may be greater than the refractive index n₂ of the protective film 700 in the second direction (e.g., x direction or −x direction) and the refractive index n₃ of the protective film 700 in the thickness direction (e.g., z-direction or −z-direction).

The direction of the maximum refractive index n₁ of the protective film 700 and the direction of the short side L1 of the camera sensor unit 410 extends may be same. An angle of view θ in a direction the short side L1 of the camera sensor unit 410 extends may be defined by Mathematical Formula 1 below. In Mathematical Formula 1 below, L may be a length of the short side L1 of the camera sensor unit 410, and f may be a focal length of the camera lens unit 30.

$$θ = 2 a tan \frac{L}{2 f} \qquad [ Mathematical Formula 1 ]$$

Referring to FIG. 7, in case that linearly polarized light enters the display device, a light pattern (e.g., a speckle) may appear on the camera sensor unit 410 due to the protective film 700 having birefringence. In case that linearly polarized light enters the display device, a concentric circle-shaped light pattern (e.g., a speckle) may appear on the camera sensor unit 410 on either side of the direction of the maximum refractive index n₁ of the protective film 700 (in other words, the first direction) (e.g., y direction or −y direction).

In one embodiment, the refractive index n₁ in the first direction (e.g., y direction or −y direction) perpendicular to the thickness direction (e.g., z direction or −z direction) of the protective film 700 of the display device, the refractive index n₂ in the second direction (e.g., x direction or −x direction) perpendicular to each of the thickness direction (e.g., z direction or −z direction) and the first direction (e.g., y direction or −y direction), and the refractive index n₃ in the thickness direction (e.g., z direction or −z direction) may satisfy Mathematical Formula 2 below.

$${n}_{1} > {n}_{3} > {n}_{2} \qquad [ Mathematical Formula 2 ]$$

An angle β from a center of the camera lens unit 30 to a center of the concentric circle-shaped light pattern appearing on the camera sensor unit 410 may be defined by Mathematical Formula 3 below.

$$β = a tan \{ \frac{{n}_{3}}{{n}_{1}} \sqrt{\frac{{( {n}_{2} )}^{2} - {( {n}_{1} )}^{2}}{{( {n}_{3} )}^{2} - {( {n}_{3} )}^{2}}} \} \qquad [ Mathematical Formula 3 ]$$

In another embodiment, the refractive index n₁ in the first direction (e.g., y direction or −y direction) perpendicular to the thickness direction (e.g., z direction or −z direction) of the protective film 700 of the display device, the refractive index n₂ in the second direction (e.g., x direction or −x direction) perpendicular to each of the thickness direction (e.g., z direction or −z direction) and the first direction (e.g., y direction or −y direction), and the refractive index n₃ in the thickness direction (e.g., z direction or −z direction) may satisfy Mathematical Formula 6 below.

$${n}_{1} > {n}_{3} > {n}_{2} \qquad [ Mathematical Formula 6 ]$$

The angle β from the center of the camera lens unit 30 to the center of the concentric circle-shaped light pattern appearing on the camera sensor unit 410 may be defined by Mathematical Formula 7 below.

$$β = a tan \{ \frac{{n}_{2}}{{n}_{1}} \sqrt{\frac{{( {n}_{3} )}^{2} - {( {n}_{1} )}^{2}}{{( {n}_{2} )}^{2} - {( {n}_{3} )}^{2}}} \} \qquad [ Mathematical Formula 7 ]$$

In case that the direction of the maximum refractive index n₁ of the protective film 700 (in other words, the first direction) (e.g., y direction or −y direction) and the direction the short side L1 of the camera sensor unit 410 extends are parallel to each other, the angle β may be greater than or similar to θ/2, and no light pattern may appear on the camera sensor portion 410, and no light pattern may be visible from the outside.

For example, in case that the direction (in other words, the first direction) (e.g., y direction or −y direction) of the maximum refractive index n₁ of the protective film 700 and the direction the short side L1 of the camera sensor unit 410 extends are parallel to each other and β≥θ/2, the light pattern appearing on the camera sensor unit may not appear on the camera sensor unit 410, or the size of the light pattern appearing on the camera sensor unit 410 may be smaller than the size in case that the direction (in other words, the first direction) (e.g., y direction or −y direction) of the maximum refractive index n₁ of the protective film 700 and the direction the long side L2 of the camera sensor unit 410 extends are parallel to each other, and consequently, the light pattern may be invisible from the outside.

Also, the size of the light pattern appearing on the camera sensor unit 410 in case that the direction (in other words, the first direction) (e.g., y direction or −y direction) of the maximum refractive index n₁ of the protective film 700 and the direction the short side L1 of the camera sensor unit 410 extends are parallel to each other and θ/2−5°≤β≤θ/2 is smaller than the size of the light pattern appearing on the camera sensor unit 410 in case that the direction (in other words, the first direction) (e.g., y direction or −y direction) of the maximum refractive index n₁ of the protective film 700 and the direction the long side L2 of the camera sensor unit 410 extends are parallel to each other, and consequently, the light pattern may be invisible from the outside.

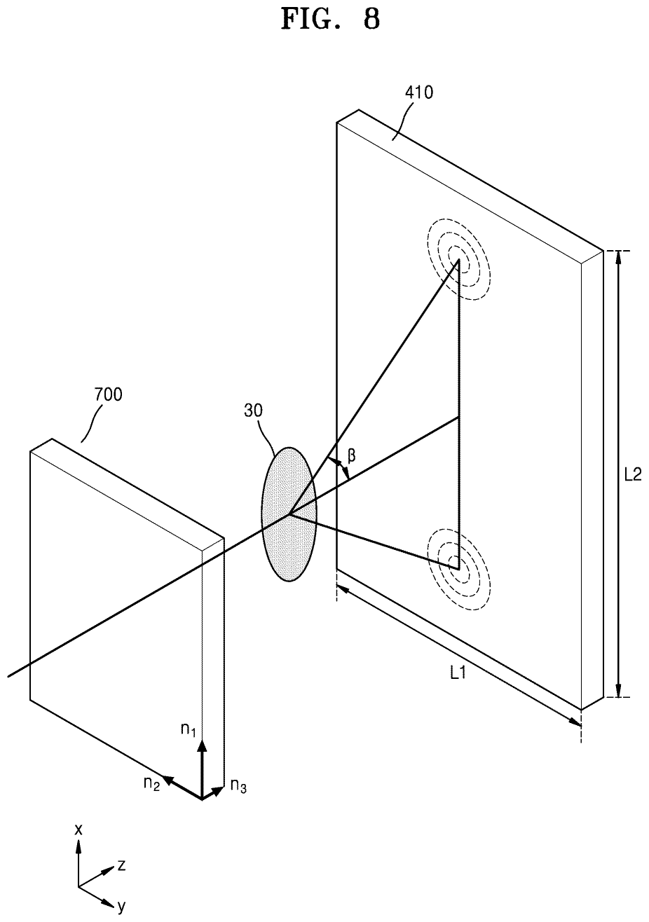

FIG. 8 is a schematic diagram of a comparative example for explaining the effects of the disclosure.

Referring to FIG. 8, in case that the direction (in other words, the first direction) (e.g., y direction or −y direction) of the maximum refractive index n₁ of the protective film 700 and the direction the long side L2 of the camera sensor unit 410 extends are parallel to each other, the long side L2 of the camera sensor unit 410 may be longer than the short side L1, and thus, a concentric circle-shaped light pattern (e.g., a speckle) may appear on the camera sensor unit 410 on both sides in a direction (in other words, the first direction) (e.g., y direction or −y direction) of the maximum refractive index n₁ of the protective film 700, and the light pattern may be visible from the outside of the display device.

According to an embodiment, in case that the direction (in other words, the first direction) (e.g., y direction or −y direction) of the maximum refractive index n₁ of the protective film 700 and the direction the short side L1 of the camera sensor unit 410 extends are parallel to each other, a light pattern (e.g., a speckle) appearing on the camera sensor unit 410 in case that linearly polarized light passes through the protective film 700 may not appear on the camera sensor unit 410, or the size of the light pattern that appears on the camera sensor unit 410 may be smaller than the size in case that the direction (in other words, the first direction) (e.g., y direction or −y direction) of the maximum refractive index n₁ of the protective film 700 and the direction of the long axis L2 of the camera sensor unit 410 are parallel to each other, and the light pattern may be invisible from the outside.

According to the embodiment described above, a display device with improved reliability and quality may be implemented. The scope of the disclosure is not limited by these effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An electronic device, comprising:
a camera sensor unit including a short side and a long side;
a camera lens unit disposed on the camera sensor unit;
a display panel disposed on the camera lens unit; and
a protective film disposed on the display panel and having birefringence, wherein
the protective film has a refractive index n₁ in a first direction perpendicular to a thickness direction of the protective film, a refractive index n₂ in a second direction perpendicular to each of the thickness direction and the first direction, and a refractive index n₃ in the thickness direction,
the refractive index n₁ is greater than the refractive index n₂ and the refractive index n₃, and
the first direction of the protective film and a direction the short side of the camera sensor unit extends are parallel to each other.

2. The electronic device of claim 1, wherein an angle of view θ of the camera lens unit in the direction the short side of the camera sensor unit extends is defined by Mathematical Formula 1,
$$θ = 2 a tan \frac{L}{2 f} \qquad [ Mathematical Formula 1 ]$$
wherein L is a length of the short side of the camera sensor unit, and
f is a focal length of the camera lens unit.

3. The electronic device of claim 2, wherein
the refractive index n₁, the refractive index n₂, and the refractive index n₃ of the protective film satisfy Mathematical Formula 2.
$${n}_{1} > {n}_{3} > {n}_{2} \qquad [ Mathematical Formula 6 ]$$

4. The electronic device of claim 3, wherein
in case that linearly polarized light passes through the protective film and the camera lens unit, a light pattern appears on the camera sensor unit.

5. The electronic device of claim 4, wherein
an angle β between a center of the camera lens unit and a center of the light pattern from the camera lens unit is defined by Mathematical Formula 3.
$$β = a tan \{ \frac{{n}_{3}}{{n}_{1}} \sqrt{\frac{{( {n}_{2} )}^{2} - {( n {1}_{} )}^{2}}{{( {n}_{3} )}^{2} - {( {n}_{2} )}^{2}} \}} \qquad [ Mathematical Formula 3 ]$$

6. The electronic device of claim 5, wherein
the angle of view θ of the camera lens unit and the angle β between the center of the camera lens unit and the center of the light pattern satisfy Mathematical Formula 4.
$$β \geq θ / 2 \qquad [ Mathematical Formula 4 ]$$

7. The electronic device of claim 5, wherein
the angle of view θ of the camera lens unit and the angle β between the center of the camera lens unit and the center of the light pattern satisfy Mathematical Formula 5.
$$θ / 2 - 5 ° \leq β \leq θ / 2 \qquad [ Mathematical Formula 5 ]$$

8. The electronic device of claim 2, wherein
the refractive index n₁, the refractive index n₂, and the refractive index n₃ of the protective film satisfy Mathematical Formula 6.
$${n}_{1} > {n}_{3} > {n}_{2} \qquad [ Mathetmatical Formula 6 ]$$

9. The electronic device of claim 8, wherein
in case that linearly polarized light passes through the protective film and the camera lens unit, a light pattern appears on the camera sensor unit.

10. The electronic device of claim 9, wherein
an angle β between a center of the camera lens unit and a center of the light pattern from the camera lens unit is defined by Mathematical Formula 7.
$$β = atan \{ \frac{{n}_{2}}{{n}_{1}} \qquad [ Mathetmatical Formula 7 ]$$

11. The electronic device of claim 10, wherein
the angle of view θ of the camera lens unit and the angle β between the center of the camera lens unit and the center of the light pattern satisfy Mathematical Formula 4.
$$β \geq θ / 2 \qquad [ Mathetmatical Formula 4 ]$$

12. The electronic device of claim 10, wherein
the angle of view θ of the camera lens unit and the angle β between the center of the camera lens unit and the center of the light pattern satisfy Mathematical Formula 5.
$$θ / 2 - 5 ° \leq β \leq θ / 2 \qquad [ Mathetmatical Formula 5 ]$$

13. The electronic device of claim 1, wherein the protective film includes polyethylene terephthalate (PET).

14. The electronic device of claim 1, wherein the display panel includes a first display area and a second display area surrounding at least a portion of the first display area.

15. The electronic device of claim 14, wherein the camera sensor unit and the camera lens unit overlap at least a portion of the second display area of the display panel in a thickness direction of the display panel.

16. The electronic device of claim 1, wherein the first direction of the protective film is a stretching direction of the protective film.

17. An electronic device comprising:
a camera sensor unit including a short side and a long side;
a camera lens unit disposed on the camera sensor unit;
a display panel disposed on the camera lens unit; and
a protective film disposed on the display panel and having birefringence, wherein
the protective film has a refractive index n₁ in a first direction perpendicular to a thickness direction of the protective film, a refractive index n₂ in a second direction perpendicular to each of the thickness direction and the first direction, and a refractive index n₃ in the thickness direction, which satisfy Mathematical Formula 2 below,
$${n}_{1} > {n}_{3} > {n}_{2} \qquad [ Mathetmatical Formula 6 ]$$
an angle of view θ of the camera lens unit in a direction the short side of the camera sensor unit extends is defined by Mathematical Formula 1,
$$θ = 2 atan \frac{L}{2 f} \qquad [ Mathetmatical Formula 1 ]$$
wherein L is a length of the short side of the camera lens unit, and f is a focal length of the camera lens unit,
in case that linearly polarized light passes through the protective film and the camera lens unit, a light pattern appears on the camera sensor unit,
an angle β between a center of the camera lens unit and a center of the light pattern from the camera lens unit is defined by Mathematical Formula 3,
$$β = atan \{ \frac{{n}_{3}}{{n}_{1}} \qquad [ Mathetmatical Formula 3 ]$$
and the angle of view θ of the camera lens unit and the angle β between the center of the camera lens unit and the center of the light pattern satisfy Mathematical Formula 8.
$$θ / 2 - 5 ° \leq β \qquad [ Mathetmatical Formula 8 ]$$

18. The electronic device of claim 17, wherein
the angle of view θ of the camera lens unit and the angle β between the center of the camera lens unit and the center of the light pattern satisfy Mathematical Formula 4.
$$β \geq θ / 2 \qquad [ Mathetmatical Formula 4 ]$$

19. An electronic device comprising:
a camera sensor unit including a short side and a long side;
a camera lens unit disposed on the camera sensor unit;
a display panel disposed on the camera lens unit; and
a protective film disposed on the display panel and having birefringence, wherein
the protective film has a refractive index n₁ in a first direction perpendicular to a thickness direction of the protective film, a refractive index n₂ in a second direction perpendicular to each of the thickness direction and the first direction, and a refractive index n₃ in the thickness direction, which satisfy Mathematical Formula 6,
$${n}_{1} > {n}_{3} > {n}_{2} \qquad [ Mathetmatical Formula 6 ]$$
an angle of view θ of the camera lens unit in a direction the short side of the camera sensor unit extends is defined by Mathematical Formula 1,
$$θ = 2 atan \frac{L}{2 f} \qquad [ Mathetmatical Formula 1 ]$$
wherein L is a length of the short side of the camera lens unit, and f is a focal length of the camera lens unit,
in case that linearly polarized light passes through the protective film and the camera lens unit, a light pattern appears on the camera sensor unit,
an angle β between a center of the camera lens unit and a center of the light pattern from the camera lens unit is defined by Mathematical Formula 7,
$$β = atan \{ \frac{{n}_{2}}{{n}_{1}} \sqrt{\frac{{( {n}_{3} )}^{2} - {( {n}_{1} )}^{2}}{{( {n}_{2} )}^{2} - {( {n}_{3} )}^{2}}} \} \qquad [ Mathetmatical Formula 7 ]$$
and the angle of view θ of the camera lens unit and the angle β between the center of the camera lens unit and the center of the light pattern satisfy Mathematical Formula 8.
$$θ / 2 - 5 ° \leq β \qquad [ Mathetmatical Formula 8 ]$$

20. The electronic device of claim 19, wherein
the angle of view θ of the camera lens unit and the angle β between the center of the camera lens unit and the center of the light pattern satisfy Mathematical Formula 4.
$$β \geq θ / 2 \qquad [ Mathetmatical Formula 4 ]$$
